(19) United States
(12) Patent Application Publication
(10) Pub. No.: US 2024/0310578 A1
(43) Pub. Date: Sep. 19, 2024

(54) CO-PACKAGED OPTICS ASSEMBLIES

(71) Applicant: CORNING RESEARCH & DEVELOPMENT CORPORATION, CORNING, NY (US)

(72) Inventor: Lars Martin Otfried Brusberg, Corning, NY (US)

(21) Appl. No.: 18/438,730

(22) Filed: Feb. 12, 2024

Related U.S. Application Data
(63) Continuation of application No. PCT/US2022/039041, filed on Aug. 1, 2022.
(60) Provisional application No. 63/231,307, filed on Aug. 10, 2021.

(51) Int. Cl. G02B 6/13; G02B 6/12; H01L 23/00; H01L 25/16

(52) U.S. Cl. CPC G02B 6/13; G02B 6/12002; H01L 25/167; H01L 24/16; H01L 2224/16225

(57) ABSTRACT

An electro-optical assembly is provided. The electro-optical assembly includes a module having a module substrate, with the module substrate having a module waveguide. The electro-optical assembly also includes a circuit board having a circuit board substrate, with the circuit board substrate having a circuit board waveguide. The electro-optical assembly also includes at least one integrated circuit proximate to the module. The module is assembled to the circuit board so that the circuit board waveguide is aligned with the module waveguide for optical coupling.

### PRIORITY APPLICATION

This application is a continuation of International Patent Application No. PCT/US2022/039041, filed on Aug. 1, 2022, which claims the benefit of priority of U.S. Provisional Application No. 63/231,307, filed Aug. 10, 2021, the content of which is relied upon and incorporated herein by reference in its entirety.

### FIELD OF THE INVENTION

Embodiments of the present invention relate to electro-optical assemblies and, more particularly, to forming electro-optical assemblies.

### BACKGROUND OF THE INVENTION

Datacenters and high-performance computing applications require power efficient high-speed interconnects. Photonic transceivers are often co-packaged with electric integrated circuits (ICs) to form co-packaged optics (CPOs). Photonic transceivers are often co-packaged with ICs like ethernet switch application specific integrated circuits (ASICs), server chips, network processing units (NPUs), graphics processing units (GPUs), etc. This decreases the length of electrical lines to a few centimeters or less.

However, CPOs must overcome critical challenges like high density optical coupling, laser source integration, and high yield photonic assembly to be considered as a viable mass market technology. Fly-over fiber interconnects above the printed circuit board (PCB) are utilized for interconnecting the CPO transceivers assembled on an organic packaging substrate with other CPOs, mid-board optical connectors, or faceplate optical connectors. For example, multi-fiber push on (MPO) connectors, Lucent connectors (LC), and mini-duplex connectors (MDC) are utilized. The CPO optical fiber interface is separated from the electrical PCB, and the existing supply chain (e.g. printed circuit board (PCB) manufacturing and outsourced assembly and testing (OSAT) ecosystem for IC packaging) build systems without fundamental changes for manufacturing. These systems use electrical sockets and fiber management solutions, resulting in reduced integration density and performance. Fiber harnesses with an increased number of fibers (e.g. 256, 1024, above) are be used in some embodiments, but these are often costly and bulky.

Furthermore, additional challenges arise regarding fiber handling, routing, reliability, and density. For example, electrical sockets are limited by pitch size of electrical inputs and outputs, and the electrical sockets require mechanical frames. Additionally, during operation, constant force is required to compress springs within the electrical sockets, making these electrical sockets more difficult to use. The footprint of the socket is also larger than the photonic and driver chips itself, and this significantly increases the overall footprint of the multi-chip module (MCM) and the electrical line length.

### SUMMARY

Electro-optical assemblies and methods for making electro-optical assemblies are provided in some embodiments herein. Two substrates may be aligned with each other and connected so that integrated optical waveguides in both substrates make an optical interconnect. Optical interconnects enable higher bandwidth density and lower power consumption as compared to electrical interconnects.

A photonic packaging concept is provided in some embodiments for coupling light by evanescent coupling and edge coupling between two substrates. One substrate is a module substrate that contains the CPOs, and the second substrate is a circuit board substrate on which the module substrate may be received. Optical fibers may be replaced by integrated waveguides in substrates for routing from one waveguide over an optical interface to another waveguide on another substrate, and the smallest waveguide pitch may be 50 microns or less. Losses of less than 0.08 decibels per centimeter may be achieved by using integrated waveguides in the substrates.

Optical interfaces may be used between a circuit board substrate and a module substrate, and this may lead to numerous advantages. These advantages include higher integration density, reduced electrical line length, a reduced number of electrical interfaces, a reduced bill of materials, and reduced assembly costs. Waveguide layers may be stacked through various approaches. For example, 3D waveguide writing and glass sheet lamination may be used.

In order to avoid electrical sockets, components may be flip-chip soldered to a module substrate. Flip-chip bonding of ICs like solder reflow or thermo-compression bonding may be performed only on a module substrate without the need to perform these processes on a circuit board substrate itself. For both substrates, different processes and technologies may be applied based on requirements and costs, and substrates may be optically bonded together to create an optical interconnect.

Waveguides integrated in both substrates may be brought in proximity to perform evanescent coupling. Substrates may be directly bonded together. Alternatively, a gap may be maintained between substrates, and the gap may be filled with an optical material like an optical adhesive, an index matching fluid, or an optical pad. The interface material may be filled with spacers to define the gap distance optimized for optical coupling efficiency. These spacers and other related materials are discussed in U.S. Provisional Patent Application No. 63/173,621, entitled “Waveguide Substrate Connection Systems and Methods”, filed Apr. 12, 2021, which is incorporated by reference herein for all purposes. The module substrate and circuit board substrate may be aligned to each other by fiducials or passive alignment features to accurately position the substrates for low loss coupling. For evanescent coupling, light may be coupled through the surfaces of the substrates, so the edges of the substrates do not require optical quality. Thousands of optical interconnects may be formed on a substrate in a single assembly step.

Additionally, edge coupling may be used in some embodiments. By using edge coupling, the optical layers of both substrates may be aligned, and the mode field may be matched to achieve the highest coupling efficiency. The coupling efficiency may be controlled by mechanical features, but optical tapers or lenses may be provided at the location of edge coupling to relax coupling tolerances from +/−1 micrometers to +/−10 micrometers or above.

Costs may be decreased and performance may be increased with higher density module fabrication. This may be done by using thin film technology on a wafer/panel level and by using a circuit board with embedded passive optical waveguides which are finally joined. Costs may also be decreased and performance may be increased by reducing the overall size of the module substrate, and this may be done by using fine-line/space electrical lines of down to 10 microns or less and by using redistribution layers, electrical bumps, vias, or copper pillars. These techniques may provide a high electrical input/output (I/O) density between the CPO and electrical integrated circuit (ICs) with up to 1000 or more I/Os. Typically, such requirements need IC process lines under clean room conditions.

Additionally, the cost of each package (e.g. wafer/panel level packaging) is directly related to the overall footprint of the substrate area. As more modules are manufactured on a circuit board, the costs for each module goes down. The circuit board, which may host the modules, may have relaxed requirements for density.

In an example embodiment, a method for forming an electro-optical assembly is provided. The method includes providing a module having a module substrate, with the module substrate having a module waveguide. The method also includes providing a circuit board having a circuit board substrate, with the circuit board substrate having a circuit board waveguide. Additionally, the method includes assembling at least one integrated circuit on the module and assembling the module to the circuit board so that the module waveguide is aligned with the circuit board waveguide for optical coupling.

In some embodiments, the at least one integrated circuit may include at least one photonic integrated circuit and an application specific integrated circuit. In some related embodiments, the at least one photonic integrated circuit may be provided on a first side of the module substrate and the application specific integrated circuit may be provided on a second side of the module substrate. The module substrate may include a via that extends through the module substrate, and the via may be configured to conduct electricity between at least two of the circuit board, the at least one photonic integrated circuit, and the application specific integrated circuit.

In some embodiments, the module may further include electrical bumps. The electrical bumps may be configured to contact the at least one photonic integrated circuit or the application specific integrated circuit. Additionally, the electrical bumps may be configured to conduct electricity between at least two of the circuit board, the at least one photonic integrated circuit, and the application specific integrated circuit. The at least one photonic integrated circuit may include two photonic integrated circuits.

In some embodiments, the at least one photonic integrated circuit may be provided on a first side of the module substrate and the application specific integrated circuit may also be provided on the first side of the module substrate. The module may further comprise electrical bumps and a redistribution layer. The electrical bumps may be configured to contact the at least one photonic integrated circuit or the application specific integrated circuit, and the redistribution layer may be configured to contact the electrical bumps. The redistribution layer and the electrical bumps may be configured to conduct electricity to or from at least two of the circuit board, the at least one photonic integrated circuit, and the application specific integrated circuit.

In some embodiments, the circuit board substrate may define a mounting plane. The module may be assembled to the circuit board so that the module substrate is provided at a different plane than the mounting plane. In some related embodiments, the circuit board substrate and the module substrate may form a recess. The recess may be formed in the mounting plane, and the at least one photonic integrated circuit may be provided in the recess.

In some embodiments, assembling the module to the circuit board may include edge coupling the module substrate to the circuit board substrate. In some related embodiments, the edge coupling may result in an edge optical interface contacting an end face of the circuit board waveguide and an end face of the module waveguide.

In some embodiments, the at least one integrated circuit may include a photonic integrated circuit waveguide. Assembling at least one integrated circuit on the module may result in the module waveguide being aligned with the photonic integrated circuit waveguide. In some embodiments, the circuit board may be separated into an electrical layer and an optical layer. A gap may be provided between the electrical layer and the optical layer, and assembling the module to the circuit board may result in the module being placed in the gap.

In some embodiments, a transitional substrate may be provided having a transitional waveguide. In some related embodiments, the transitional substrate may be assembled to the module and the circuit board. The circuit board substrate may define a mounting plane. The module substrate may be provided in the mounting plane and the transitional substrate may not be provided in the mounting plane. The transitional waveguide may be aligned with both the module waveguide and the circuit board waveguide.

In some embodiments, the module waveguide may be a glass waveguide, a polymer waveguide, or a silicon nitrate waveguide. Further, the circuit board waveguide may be a glass waveguide, a polymer waveguide, or a silicon nitrate waveguide. Additionally, in some embodiments, the module substrate and the circuit board substrate may be glass substrates.

In another example embodiment, an electro-optical assembly is provided. The electro-optical assembly includes a module having a module substrate, with the module substrate having a module waveguide. The electro-optical assembly also includes a circuit board having a circuit board substrate, with the circuit board substrate having a circuit board waveguide. The electro-optical assembly also includes at least one integrated circuit proximate to the module. The module is assembled to the circuit board so that the circuit board waveguide is aligned with the module waveguide for optical coupling.

In some embodiments, the at least one integrated circuit may include at least one photonic integrated circuit and an application specific integrated circuit. In some related embodiments, the at least one photonic integrated circuit may be provided on a first side of the module substrate and the application specific integrated circuit may be provided on a second side of the module substrate. The module substrate may include a via that extends through the module substrate, and the via may be configured to conduct electricity to or from at least two of the circuit board, the at least one photonic integrated circuit, and the application specific integrated circuit. In other related embodiments, the at least one photonic integrated circuit may be provided on a first side of the module substrate, and the application specific integrated circuit may also be provided on the first side of the module substrate. The module may further comprise electrical bumps and a redistribution layer. The electrical bumps may be configured to contact the at least one photonic integrated circuit or the application specific integrated circuit, and the redistribution layer may be configured to contact the electrical bumps. The redistribution layer and the electrical bumps may be configured to conduct electricity to or from at least two of the circuit board, the at least one photonic integrated circuit and the application specific integrated circuit.

In some embodiments, the circuit board substrate may define a mounting plane, and the module may be assembled to the circuit board so that the module substrate is provided at a different plane than the mounting plane. The circuit board substrate and the module substrate may form a recess, and the recess may be formed in the mounting plane. The at least one photonic integrated circuit may be provided in the recess.

In some embodiments, the electro-optical assembly may further include a transitional substrate having a transitional waveguide. The transitional substrate may be assembled to the module and the circuit board, and the circuit board substrate may define a mounting plane. The module substrate may be provided in the mounting plane, and the transitional substrate may not be provided in the mounting plane. The transitional waveguide may be aligned with both the module waveguide and the circuit board waveguide. Additionally, in some embodiments, an edge optical interface may contact an end face of the circuit board waveguide and an end face of the module waveguide.

In another example embodiment, an electro-optical assembly is provided that is produced by certain process. This process includes providing a module having a module substrate, with the module substrate having a module waveguide. The process also includes providing a circuit board having a circuit board substrate, with the circuit board substrate having a circuit board waveguide. The process also includes assembling at least one integrated circuit on the module and assembling the module to the circuit board so that the module waveguide is aligned with the circuit board waveguide.

In some embodiments, the process may also include forming one or more conducting elements, and the one or more conducting elements may include at least one of a via, a redistribution layer, an electrical bump, or an electrical conductor. The at least one integrated circuit may include at least one photonic integrated circuit and an application specific integrated circuit. The one or more conducting elements may be configured to conduct electricity to or from at least two of the circuit board, the at least one photonic integrated circuit, and the application specific integrated circuit.

Further areas of applicability of the present invention will become apparent from the detailed description provided hereinafter. It should be understood that the detailed description and specific examples, while indicating example preferred embodiments of the invention, are intended for purposes of illustration only and are not intended to limit the scope of the invention.

### BRIEF DESCRIPTION OF THE DRAWINGS

The present invention will become more fully understood from the detailed description and the accompanying drawings, which are not necessarily to scale, wherein:

FIG. 1A illustrates a schematic view of circuit board for routing optical signals, in accordance with some embodiments discussed herein;

FIG. 1B illustrates a schematic view of an example module, in accordance with some embodiments discussed herein;

FIG. 1C illustrates a schematic view of an example module secured to an example circuit board with one or more optical interfaces, in accordance with some embodiments discussed herein;

FIG. 2A illustrates a schematic view of an example module secured to an example circuit board, with an optical interface between the two, in accordance with some embodiments discussed herein;

FIG. 2B illustrates an enhanced view of the module, circuit board, and optical interface illustrated in FIG. 2A;

FIG. 3A illustrates a schematic view of another example module secured to an example circuit board, with an optical interface between the two, in accordance with some embodiments discussed herein;

FIG. 3B illustrates an enhanced view of the module, circuit board, and optical interface illustrated in FIG. 3A;

FIG. 4A illustrates a schematic view of another example module secured to an example circuit board, with an optical interface between the two, in accordance with some embodiments discussed herein;

FIG. 4B illustrates an enhanced view of the module, circuit board, and optical interface illustrated in FIG. 4A;

FIG. 5A illustrates a schematic view of an example transitional substrate that may be used in conjunction with a module and a circuit board, in accordance with some embodiments discussed herein;

FIG. 5B illustrates an enhanced view of the transitional substrate, the module, and the circuit board illustrated in FIG. 5A;

FIG. 6A illustrates a schematic view of an example module secured to an example circuit board, with an edge optical interface between the two, in accordance with some embodiments discussed herein;

FIG. 6B illustrates an enhanced view of the module, circuit board, and the edge optical interface illustrated in FIG. 6A;

FIG. 7A illustrates a schematic view of another example module secured to an example circuit board, with an optical interface between the two, in accordance with some embodiments discussed herein;

FIG. 7B illustrates an enhanced view of the module, circuit board, and optical interface illustrated in FIG. 7A;

FIG. 8A is a flow chart illustrating an example method for forming an electro-optical assembly, in accordance with some embodiments discussed herein; and

FIG. 8B is a flow chart illustrating another example method for forming an electro-optical assembly, in accordance with some embodiments discussed herein.

### DETAILED DESCRIPTION

The following description of the embodiments of the present invention is merely exemplary in nature and is in no way intended to limit the invention, its application, or uses. The following description is provided herein solely by way of example for purposes of providing an enabling disclosure of the invention, but does not limit the scope or substance of the invention.

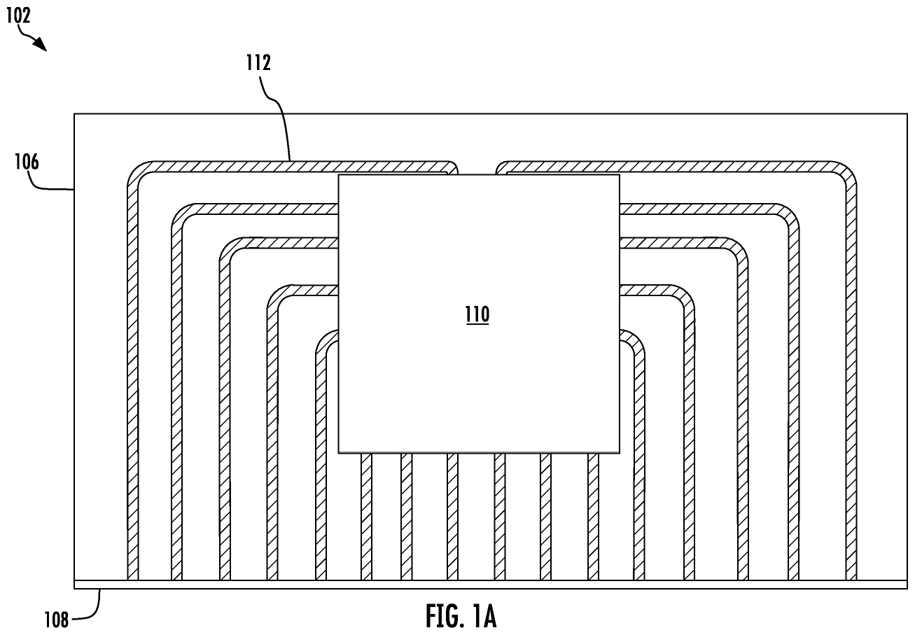

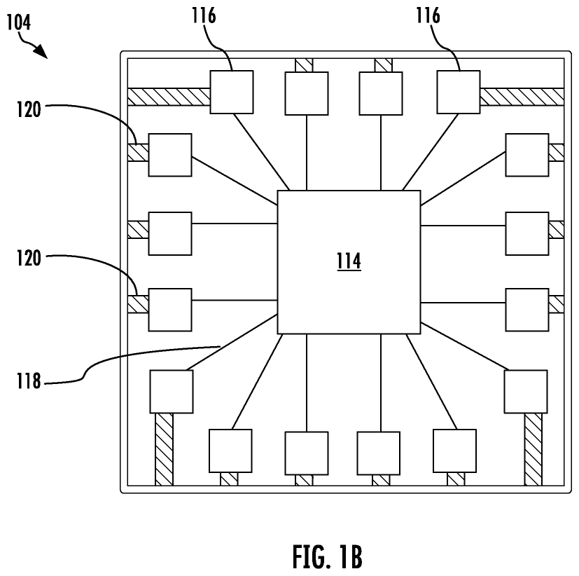

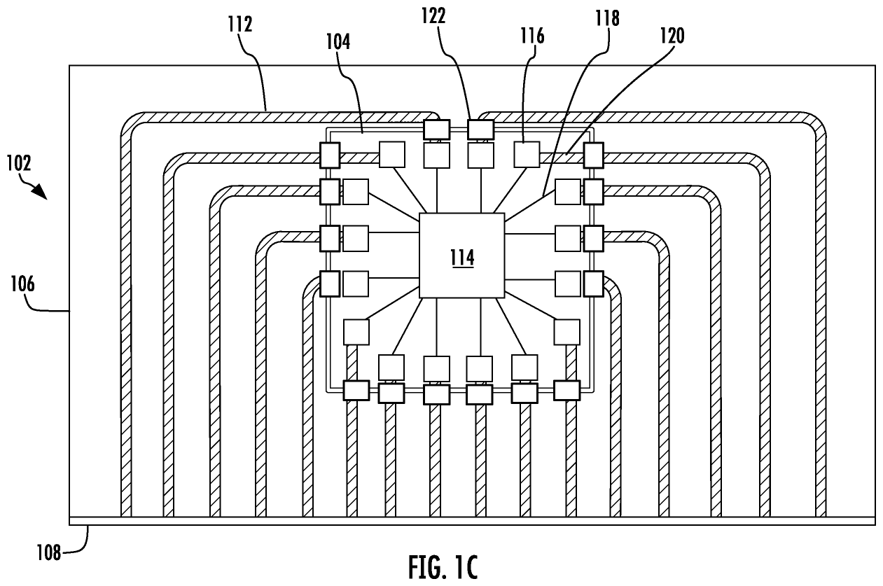

Like numerals within FIGS. 1A-1C, 2A, 2B, 3A, 3C, 4A, 4B, 5A, 5B, 6A, 6B, 7A, and 7B are intended to refer to similar features. For example, elements 104, 204, 304, etc. are each representative of a module.

In various embodiments, circuit boards are provided with a cavity, and the circuit boards are configured to receive a module with CPOs and ICs within the cavity. FIG. 1A illustrates a schematic view of an example circuit board 102 for routing optical signals. The circuit board 102 may include a circuit board substrate 106 and a front plate 108. The circuit board substrate 106 may define a cavity 110, and the circuit board substrate 106 may be configured to receive a module 104 (see FIGS. 1B-1C) in the cavity 110. One or more circuit board waveguides 112 may also be provided in the circuit board substrate 106. These circuit board waveguides 112 may extend from the front plate 108 and through the circuit board substrate 106 to the edge of the cavity 110. However, in some embodiments, circuit board waveguides may extend from a mid plane or a backplane and through the circuit board substrate to the edge of the cavity. Circuit board waveguides 112 may be surface or subsurface waveguides. In the illustrated embodiment, the circuit board 102 has a size of 420 mm×250 mm, but circuit boards may be provided with other dimensions as well.

Various CPOs and ICs may be installed on a module, and this module may be assembled to a circuit board. FIG. 1B illustrates a schematic view of an example module 104. In some embodiments, the module 104 may be a multi-chip module (MCM), but other components may also be used. Various components may be assembled to the module substrate. This assembly may be done through flip-chip soldering. Fine-pitch flip-chip bonding of ICs through solder reflow or thermo-compression bonding may be performed only on a module substrate without the need to perform these processes on a circuit board substrate itself, reducing the costs of manufacturing these modules and circuit boards and reducing the costs of assembling and interconnecting a module to a circuit board.

At least one integrated circuit may be assembled to the module 104 in some embodiments. In the illustrated embodiment, the module 104 includes an application specific integrated circuit (ASIC) 114 and one or more photonic integrated circuits (PICs) 116. In the illustrated embodiment, the module 104 has sixteen PICs that are connected to an array of optical waveguides. However, a greater or lesser number of PICs 116 may be provided on the module 104. One or more electrical lines 118 may connect the ASIC 114 and the PICs 116. In some embodiments, the electrical lines 118 may also be utilized to form electrical connections with other components. The module 104 may also include a module substrate with one or more module waveguides 120. The one or more module waveguides 120 may be surface or subsurface waveguides. The total number of module waveguides 120 may be equal to the total number of circuit board waveguides 112 in some embodiments, and these waveguides 112, 120 may be positioned so that they may be easily aligned for optical coupling when the module 104 is placed in the cavity 110 of the circuit board 102. A person of ordinary skill in the art would recognize that waveguides 112, 120 may be aligned whenever effective optical alignment is permitted. For example, alignment may occur where the waveguides fall within tolerances of +/−10 micrometers, but larger and smaller tolerances may be used as well. In the illustrated embodiment, the module 104 has a size of 100 mm×100 mm, but modules may be provided with other dimensions as well. The cavity 110 of the circuit board substrate 106 may have a size that is similar to the size of the module 104.

The module 104 illustrated in FIG. 1B may be assembled with the circuit board 102 illustrated in FIG. 1A. FIG. 1C illustrates a schematic view of an example electro-optical assembly with a module 104 secured to an example circuit board 102. As illustrated, circuit board waveguides 112 may be aligned with module waveguides 120, and optical interfaces 122 may be utilized to form a coupling interface for optical coupling between the circuit board waveguides 112 and the module waveguides 120. In the illustrated embodiment, sixteen waveguide groups are provided in both the circuit board 102 and the module 104, with a plurality of waveguides provided in each waveguide group. In some embodiments, the optical interface 122 may be an optical evanescent coupling interface. U.S. Provisional Patent Application No. 63/173,621, entitled “Waveguide Substrate Connection Systems and Methods”, filed Apr. 12, 2021, which is incorporated herein by reference, discusses additional details regarding the spacers, optical evanescent coupling interfaces, and other related materials. The circuit board waveguides 112 and the module waveguides 120 may be provided with a waveguide pitch of 50 microns or less, and losses of less than 0.08 decibels per centimeter may be achieved by using integrated waveguides in the substrates.

Various assemblies and methods for forming such assemblies with a circuit board 102 and one or more modules 104 are described herein, and these each result in high density assemblies. Higher density assemblies may lead to lower costs and higher performance. The cost of each assembly is directly related to the overall footprint of the substrate area. Multiple modules 104 may be assembled on the circuit board 102 at various locations on the circuit board. As more modules are manufactured on a circuit board, the costs for each module goes down.

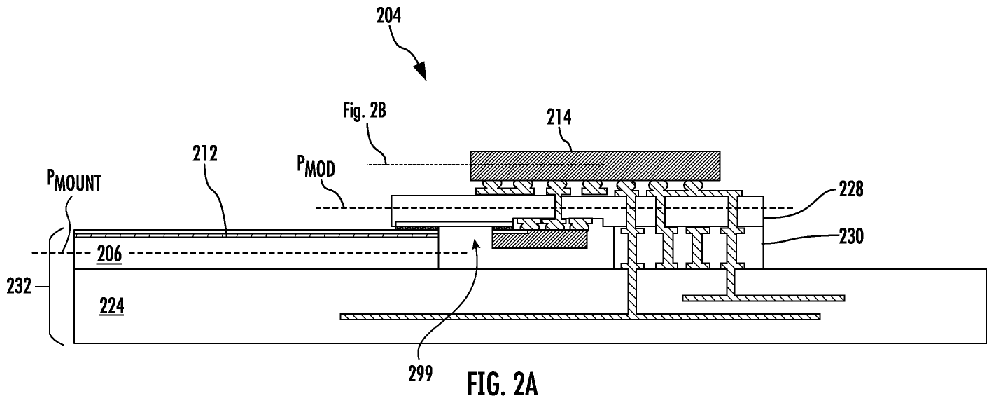

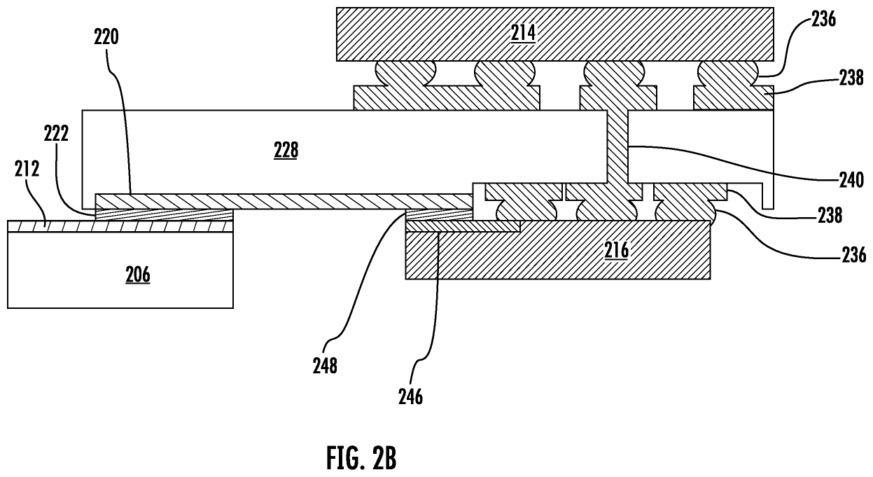

FIG. 2A illustrates a schematic view of one example module 204 secured to an example circuit board 232, with an optical interface between the two. FIG. 2B illustrates an enhanced view of the module 204, circuit board 232, and optical interface 222 illustrated in FIG. 2A. As noted above, the module 204 and the circuit board 232 may be separately fabricated and tested.

The circuit board 232 may include a circuit board substrate 206 having one or more circuit board waveguides 212. In some embodiments, the circuit board 232 may include a printed circuit board (PCB). The circuit board substrate 206 and the one or more circuit board waveguides 212 disposed therein/thereon may form an optical layer of the circuit board 232, and the circuit board 232 may also include an electrical layer 224. The circuit board substrate 206 may be made of glass, but other materials or combinations of materials may also be used in some embodiments. Additionally, circuit board waveguides 212 and module waveguides 220 may include glass waveguides, polymer waveguides, or silicon nitrate waveguides.

An electrical interface 230 may be provided that is configured to conduct electricity between components of the module 204 and the circuit board 232. The electrical interface 230 may include one or more vias 240 (see FIG. 2B) or other electrical conductors. In some embodiments, the electrical interface 230 may extend between the module substrate 228 and the electrical layer 224 of the circuit board 232. A wide variety of components may be used as an electrical interface 230. For example, an electrical socket, a land grid array (LGA), one or more solder bumps, one or more wire bonds, an electrical conductor, a conductive adhesive, etc. may be used.

Looking now at FIG. 2B, the module 204 may include a module substrate 228. The module substrate 228 may be made of glass, but other materials or combinations of materials may also be used in some embodiments. One or more module waveguides 220 may be provided in/on the module substrate 228. Additionally, one or more integrated circuits may be assembled on the module 204. In some embodiments, at least one PIC 216 and an ASIC 214 may be assembled on the module 204. In the illustrated embodiment of FIG. 2B, one PIC 216 and one ASIC 214 are assembled on the module 204. The circuit board substrate 206 may define a mounting plane (P_{MOUNT}). In the illustrated embodiment, the module substrate 228 is provided at a different plane (P_{MOD}) than the mounting plane of the circuit board substrate 206, with the circuit board substrate 206 being vertically offset from the module substrate 228. However, the circuit board substrate 206 and the module substrate 228 may be provided in the same plane in some embodiments. It should be understood that the circuit board substrate 206 and the module substrate 228 may be oriented in any manner and that these substrates are not required to lie flat as illustrated in FIG. 2B.

In the illustrated embodiment, the PIC 216 is provided on a first side (the bottom side in the illustrated example) of the module substrate 228, and the ASIC 214 is provided on a second side (the top side of the illustrated example) of the module substrate 228. Vias 240, redistribution layers 238, electrical bumps 236, and other conductors may be provided to assist in conducting electricity between the circuit board 232, the PIC 216, and/or the ASIC 214. The module substrate 228 may include one or more vias 240 that extend through the module substrate 228. The via(s) 240 may be configured to conduct electricity to or from at least two of the circuit board 232, the PIC 216, and the ASIC 214. Electrical bumps 236 may be configured to contact the PIC 216 or the ASIC 214, and the electrical bumps 236 may be configured to conduct electricity to or from the ASIC 214, the PIC 216, and/or the circuit board 232. Redistribution layers 238 may also be provided, and these redistribution layers 238 may also be configured to conduct electricity to or from at least two of the ASIC 214, the PIC 216, and/or the circuit board 232. The use of these vias 240, redistribution layers 238, and electrical bumps 236 may result in higher density electro-optical assemblies.

The PIC 216 is provided directly below the ASIC 214 in the illustrated embodiment of FIGS. 2A-2B. By doing this, the total electrical line length may be reduced, and this may reduce the amount of material required for redistribution layers 238 and vias 240. However, as illustrated in additional embodiments below, the PIC 216 may be positioned elsewhere.

The PIC 216 may comprise silicon in some embodiments, but other materials may be used. The PIC 216 may include a PIC waveguide 246. The module waveguide 220 may be aligned with the PIC waveguide 246. Additionally, the circuit board substrate 206 and the module substrate 228 may form a recess 299 (e.g., the space between the circuit board substrate 206 and the electrical interface 230) as illustrated in FIGS. 2A-2B, and the recess 299 may be formed in the same plane as the mounting plane (P_{MOUNT}) and the circuit board substrate 206. The PIC 216 may be provided in the recess 299 as illustrated in FIGS. 2A-2B.

One or more coupling interfaces may be provided. For example, in the illustrated embodiment, an optical interface 222 and a PIC optical interface 248 are provided. Optical interface may enable higher bandwidth density and lower power consumption as compared to electrical interconnects. Additionally, the use of optical interfaces may result in higher integration densities, reduced electrical line lengths, a reduced number of electrical interfaces, a reduced bill of materials, and reduced assembly costs. The optical interface 222 may be provided between the circuit board waveguide(s) 212 and the module waveguide(s) 220. The PIC optical interface 248 may be provided between the module waveguide(s) 220 and the PIC waveguide(s) 246. In some embodiments, the circuit board substrate 206 and the module substrate 228 may be made of glass, so the optical interface 222 may be configured to optimize glass-to-glass waveguide coupling. Additionally, the PIC 216 may comprise silicon in some embodiments, so the PIC optical interface 248 may be configured to optimize glass-to-silicon waveguide coupling in some embodiments.

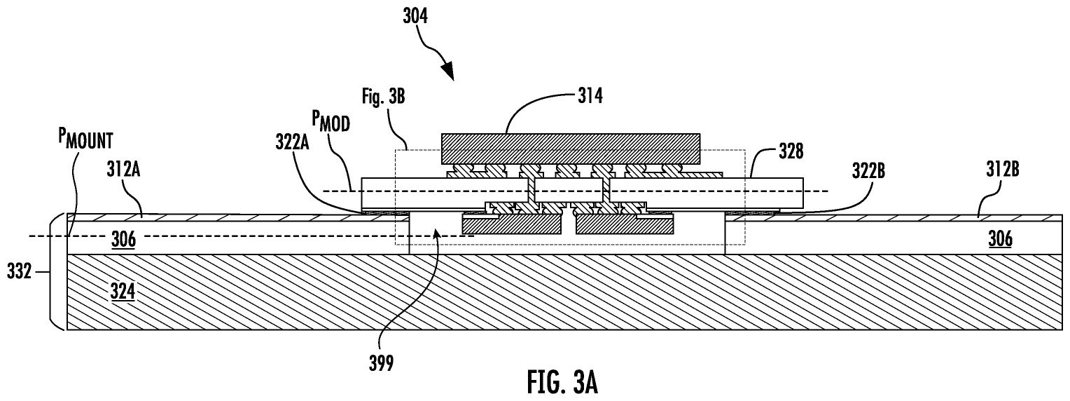

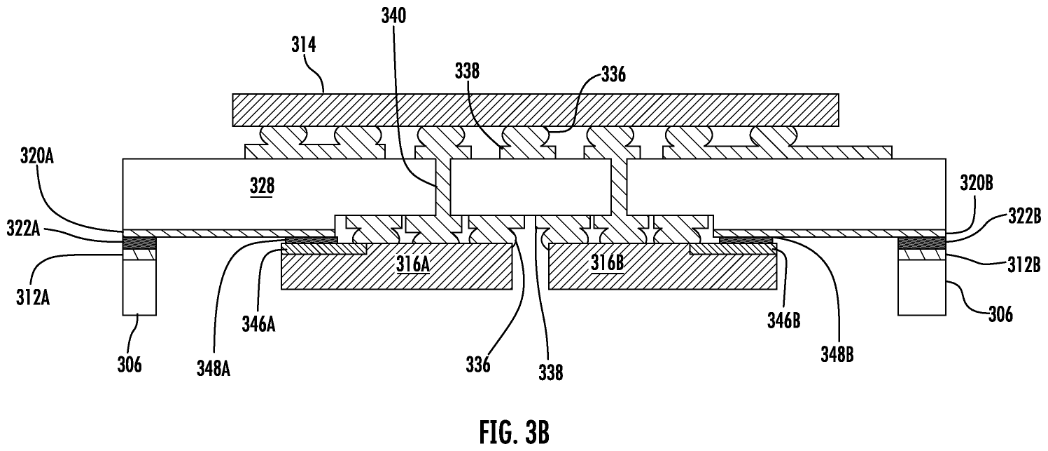

In some embodiments, a module may include waveguides on multiple sides, and the module may be configured to be assembled to a circuit board so that these waveguides are optically coupled to corresponding waveguides of the circuit board. FIG. 3A illustrates a schematic view of an example module secured to an example circuit board and an optical interface between the two. FIG. 3B illustrates an enhanced view of the module, circuit board, and optical interface illustrated in FIG. 3A. The electro-optical assembly illustrated in FIG. 3A-3B is similar to the electro-optical assembly illustrated in FIGS. 2A-2B in several respects. For example, a circuit board 332 is provided with an electrical layer 324 and an optical layer formed by a circuit board substrate 306 with circuit board waveguides 312A, 312B provided therein. Similarly, a module 304 is provided with a module substrate 328 and an ASIC 314 assembled on the module substrate 328.

Unlike the embodiment illustrated in FIG. 2A-2B, the embodiment illustrated in FIG. 3A-3B includes a first set of one or more module waveguides 320A and a second set of one or more module waveguides 320B secured in the module substrate 328. A first optical interface 322A may be provided between the first set of one or more module waveguides 320A and a first set of one or more circuit board waveguides 312A. Similarly, a second optical interface 322B may be provided between the second set of one or more module waveguides 320B and a second set of one or more circuit board waveguides 312B.

Additionally, unlike the embodiment illustrated in FIG. 2A-2B, the embodiment illustrated in FIG. 3A-3B has two PICs, including a first PIC 316A and a second PIC 316B. Notably, the two PICs are physically positioned within a recess 399 formed between two sides of the circuit board substrate 306 (e.g., the module substrate 328 is mounted in a mounting plane P_{MOD} that is offset vertically from the mounting plane P_{MOUNT} of the circuit board substrate 306). The first PIC 316A may comprise a first set of one or more PIC waveguides 346A, and a first PIC optical interface 348A may be provided between the first set of one or more module waveguides 320A and the first set of one or more PIC waveguides 346A. The second PIC 316B may comprise a second set of one or more PIC waveguides 346B, and a second PIC optical interface 348B may be provided between the second set of one or more module waveguides 320B and the second set of one or more PIC waveguides 346B.

Similar to the embodiments illustrated in FIGS. 2A-2B, electrical bumps 336, redistribution layers 338, and vias 340 may be provided. These components and other conductors may be configured to conduct electricity to or from at least two of the ASIC 314, the first PIC 316A, and the second PIC 316B. Electrical interfaces may be provided inside of one or more cavities in the module substrate 328, and these cavities may be provided away from the module waveguides 320A, 320B. These cavities may be formed through a wide variety of approaches, including but not limited to etching, lasering, machining, etc. Vias 340 may be provided in the cavities. However, electrical bumps 336 may be provided in the cavities in some embodiments. Where this is done, two substrates may be placed in close contact with each other to permit evanescent coupling between optical waveguides in the two substrates.

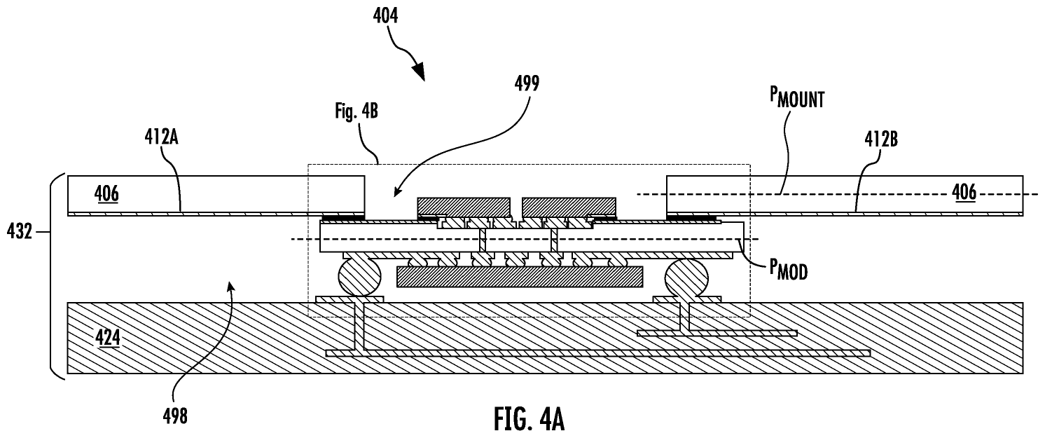

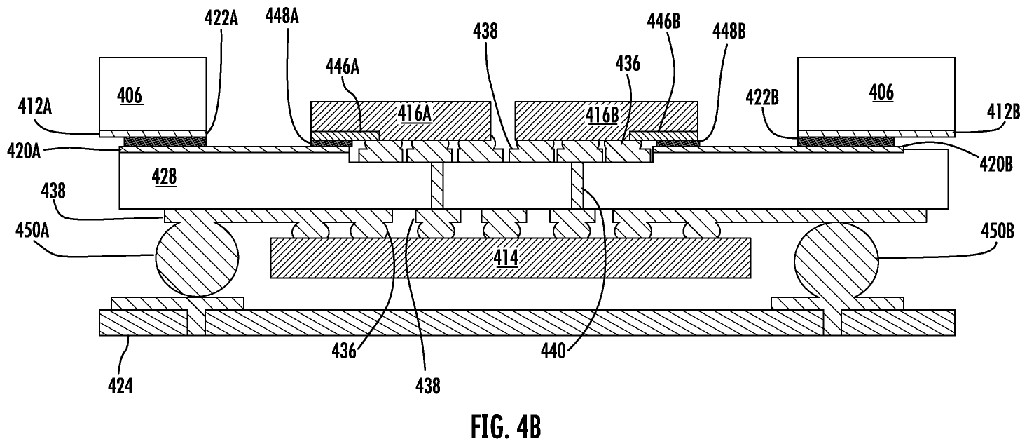

In some embodiments, the optical layer and electrical layer of the circuit board may be separate, and the module may be assembled in a gap that is formed between the two layers. FIG. 4A illustrates a schematic view of an example module secured to an example circuit board and an optical interface between the two. FIG. 4B illustrates an enhanced view of the module, circuit board, and optical interface illustrated in FIG. 4A. The electro-optical assembly illustrated in FIGS. 4A-4B is similar to the electro-optical assembly illustrated in FIGS. 3A-3B. For example, a circuit board 432 is provided have a gap 498 between an electrical layer 424 and an optical layer formed by a circuit board substrate 406 with circuit board waveguides 412A, 412B provided therein/thereon. Similarly, a module 404 is provided with a module substrate 428 and an ASIC 414 assembled on the module substrate 428.

Additionally, the embodiment illustrated in FIG. 4A-4B includes a first set of one or more module waveguides 420A and a second set of one or more module waveguides 420B secured in the module substrate 428. A first optical interface 422A may be provided between the first set of one or more module waveguides 420A and a first set of one or more circuit board waveguides 412A. Similarly, a second optical interface 422B may be provided between the second set of one or more module waveguides 420B and a second set of one or more circuit board waveguides 412B.

Furthermore, the embodiment illustrated in FIG. 4A-4B has two PICs, including a first PIC 416A and a second PIC 416B. Notably, the two PICs are physically positioned within a recess 499 formed between two sides of the circuit board substrate 406 (e.g., the module substrate 428 is mounted in a mounting plane P_{MOD} that is offset vertically from the mounting plane P_{MOUNT} of the circuit board substrate 406). The first PIC 416A may comprise a first set of one or more PIC waveguides 446A, and a first PIC optical interface 448A may be provided between the first set of one or more module waveguides 420A and the first set of one or more PIC waveguides 446A. The second PIC 416B may comprise a second set of one or more PIC waveguides 446B, and a second PIC optical interface 448B may be provided between the second set of one or more module waveguides 420B and the second set of one or more PIC waveguides 446B.

Similar to the embodiments described above, electrical bumps 436, redistribution layers 438, and vias 440 may be provided. These components and other conductors may be configured to conduct electricity to or from at least two of the circuit board 432, the first PIC 416A, the second PIC 416B, and the ASIC 414.

The circuit board 432 may also be separated into an electrical layer 424 and an optical layer (circuit board substrate 406 and circuit board waveguides 412A or 412B therein). Unlike the embodiments described above, a gap 498 may be provided between the electrical layer 424 and the optical layer as illustrated in FIGS. 4A-4B. The module 404 may be provided in the gap as illustrated in FIGS. 4A-4B.

A first conductor 450A and a second conductor 450B may also be provided. The first conductor 450A and the second conductor 450B may be configured to conduct electricity between electrical components of the module 404 and the circuit board 432. The first conductor 450A and the second conductor 450B may also be configured to maintain the module at a certain distance away from the electrical layer 424 of the circuit board 432. The first conductor 450A and the second conductor 450B may also be configured to maintain the gap between the circuit board substrate 406 and the electrical layer 424 of the circuit board 432. In some embodiments, the conductors 450A, 450B may be solder bumps, but other components may be used as well.

Additionally, the embodiment illustrated in FIGS. 4A-4B differs in that the ASIC 414 is provided on the bottom side of the module substrate 428 and the first PIC 416A and the second PIC 416B are provided on the top side of the module substrate 428. This differs from the previous embodiments, where the ASIC 214, 314 is provided on the top side of the module substrate 228, 328 and any PICs 216, 316A, 316B are provided on the bottom side of the module substrate 228, 328.

The circuit board 432 has optical waveguides 412A, 412B, and the circuit board 432 may be one large glass panel/sheet that is free-from cut with shapes like openings or stripes that connect with the module 404 or other ports like fiber connectors. Additionally, the circuit board substrate 432 may have a wide variety of thicknesses, and the thickness may be selected to meet the design needs for a particular task. For example, thicker circuit board substrates 406 may be provided with a thickness of 300-700 μm to make the circuit board substrate 406 more rigid, or thinner circuit board substrates 406 may be used with a thickness of 50-300 μm to make the circuit board substrate 406 more flexible. Where more flexible circuit board substrates 406 comprising glass are used, the glass may bend to compensate for different heights of the module(s) 404 or fiber connector interfaces (e.g. a face plate or a backplane).

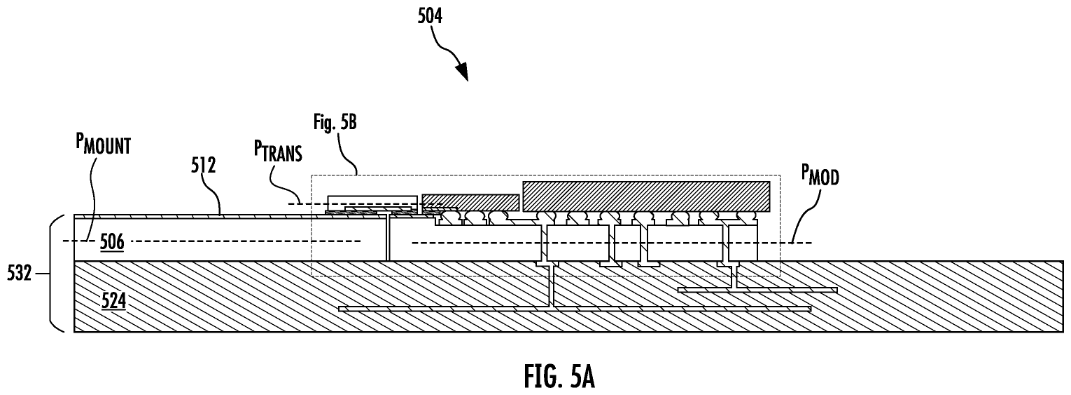

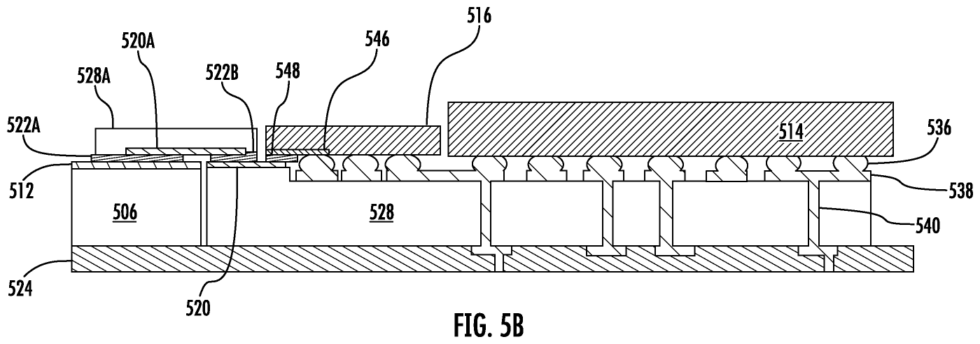

Additional transitional substrates may be used in some embodiments to permit a user to tailor the assembly to his or her needs. FIG. 5A illustrates a schematic view of a transitional substrate 528A securing an example module 504 and an example circuit board 532. FIG. 5B illustrates an enhanced view of the transitional substrate 528A, the example module 504, and the example circuit board 532 illustrated in FIG. 5A.

Similar to the embodiments described above, the embodiment illustrated in FIGS. 5A and 5B includes a module 504 with a module substrate 528. The module substrate 528 may include one or more module waveguides 520. A circuit board substrate 506 may also be provided with one or more circuit board waveguides 512. In the illustrated embodiment, the mounting plane (P_{MOUNT}) defined by the circuit board substrate 506 and the plane (P_{MOD}) of the module substrate 528 (see FIG. 5B) are co-planar.

Looking now at FIG. 5B, additional features may be seen more clearly. The electro-optical assembly may include a transitional substrate 528A having one or more transitional waveguides 520A as illustrated in FIG. 5B. In some embodiments, the transitional substrate 528A may be assembled to the module substrate 528 of the module 504, and the transitional substrate 528A may also be assembled to the circuit board substrate 506 of the circuit board 532. The mounting plane (P_{MOUNT}) defined by the circuit board substrate 506 may be provided in the same plane (P_{MOD}) as the module substrate 528, and the transitional substrate 528A may be provided in a different plane (P_{TRANS}) than the circuit board substrate 506 and the module substrate 528. The transitional waveguide(s) 520A may be aligned with both the module waveguide(s) 520 and the circuit board waveguide(s) 512. A first optical interface 522A may be provided between the transitional waveguide(s) 520A and the circuit board waveguide(s) 512. Similarly, a second optical interface 522B may be provided between the transitional waveguide(s) 520A and the module waveguide(s) 520. The transitional waveguides 520A may be used to bridge the gap between the circuit board waveguide(s) 512 and the module waveguide(s) 520. Transitional substrates 528A may be made of various materials, and a material like glass may be used in some embodiments. Waveguides may be laser-written in some embodiments, and this may overcome issues with misalignment (angular, lateral, height, etc.).

A PIC 516 may also be provided. This PIC 516 may include one or more PIC waveguide(s) 546. A PIC optical interface 548 may be provided between the PIC waveguide(s) 546 and the module waveguide(s). In the illustrated embodiment, the PIC 516 is provided on a first side (the top side in the illustrated embodiment) of the module substrate 528, and the ASIC 514 is also provided on the first side of the module substrate 528. The module 504 also includes electrical bumps 536, redistribution layers 538, and vias 540. The electrical bumps 536 are configured to contact the PIC 516 or the ASIC 514, and the redistribution layer 538 is configured to contact the electrical bumps 536. The electrical bumps 536, the redistribution layer 538, and the vias 540 are configured to conduct electricity to or from at least two of the ASIC 514, the PIC 516, and the electrical layer 524 of the circuit board 532.

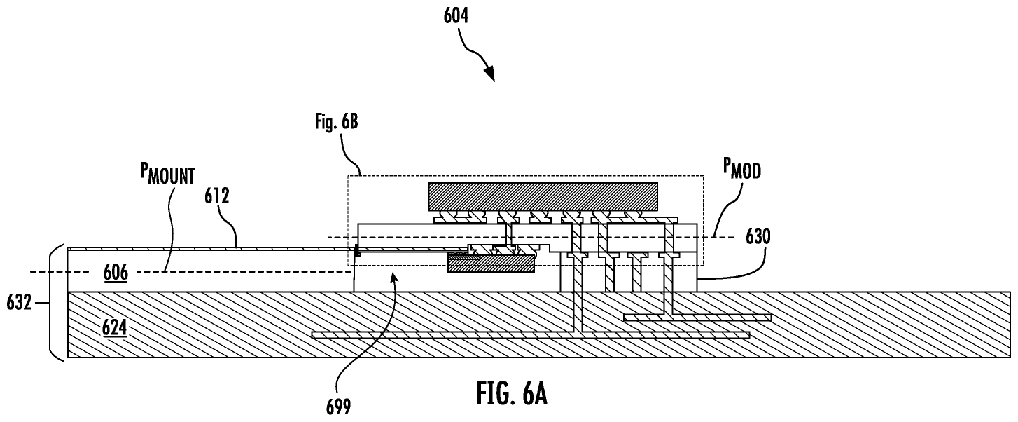

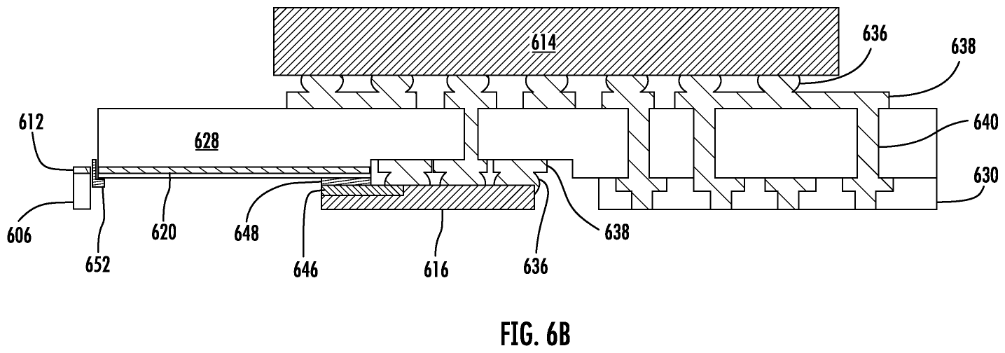

Edge optical interfaces may be used in some embodiments. An edge optical interface may be configured to contact an end face of a circuit board waveguide and an end face of a module waveguide. FIG. 6A illustrates a schematic view of an example module secured to an example circuit board, with an edge optical interface between the two. FIG. 6B illustrates an enhanced view of the module, circuit board, and the edge optical interface illustrated in FIG. 6A.

Similar to the embodiments described above, the embodiment illustrated in FIGS. 6A and 6B includes a module 604 with a module substrate 628. The module substrate 628 may include one or more module waveguides 620. A circuit board 632 may also be provided with a circuit board substrate 606, and the circuit board substrate 606 may have one or more circuit board waveguides 612. The circuit board substrate 606 may define a mounting plane (P_{MOUNT}). In the illustrated embodiment, the module substrate 628 is provided at a different plane (P_{MOD}) than the mounting plane (P_{MOUNT}), with the module substrate 628 provided above the circuit board substrate 606.

An electrical interface 630 may be provided as well. The electrical interface 630 may be configured to conduct electricity between components of the module 604 and the circuit board 632. The electrical interface 630 may include one or more vias 640 or other electrical conductors. In some embodiments, the electrical interface 630 may extend between the module substrate 628 and the electrical layer 624 of the circuit board 632. The module 604 may also include electrical bumps 636, redistribution layers 638, and vias 640. The electrical bumps 636 are configured to contact the PIC 616 or the ASIC 614, and the redistribution layers 638 are configured to contact the electrical bumps 636. The electrical bumps 636, the redistribution layers 638, and the vias 640 may be configured to conduct electricity to or from at least two of the ASIC 614, the PIC 616, and the electrical layer 624 of the circuit board 632.

Similar to previous embodiments, the module 604 is provided with an ASIC 614 and a PIC 616 assembled on the module substrate 628. As a result of the mounting plane (P_{MOUNT}) defined by the circuit board substrate 606 and the module plane (P_{MOD}) of the module substrate 628 being provided in different planes, a recess 699 is formed in the area beneath the module substrate 628 and within the same plane as the circuit board substrate 606 (within the mounting plane (P_{MOUNT})). The PIC 616 is provided in this recess 699 in the illustrated embodiment. The PIC 616 may include one or more PIC waveguide(s) 646, and a PIC optical interface 648 may be provided between the module waveguide(s) 620 and the PIC waveguide(s) 646.

In the illustrated embodiment, an edge optical interface 652 is utilized. The edge optical interface 652 may contact an end face of a circuit board waveguide of the circuit board waveguide(s) 612. The edge optical interface 652 may also contact an end face of a module waveguide of the module waveguide(s) 620. The edge optical interface 652 may include lenses or index matching material, and this material may reduce back-reflection. Alternatively or in addition, an anti-reflection coating may be provided in the edge optical interface 652. In some embodiments, mechanical features such as trenches, pins, cavities, steps, fiducials, etc. may be used to support alignment between the module waveguide(s) 620 and the circuit board waveguide(s) 612 for optical coupling. The circuit board waveguide(s) 612 may be aligned with the module waveguides 620 in the vertical and lateral directions to optimize edge coupling. The coupling efficiency at the edge optical interface 652 may be controlled by mechanical features, and optical tapers or lenses may be provided at the location of edge coupling interface 652 to relax coupling tolerances from +/−1 micrometers to +/−10 micrometers or above.

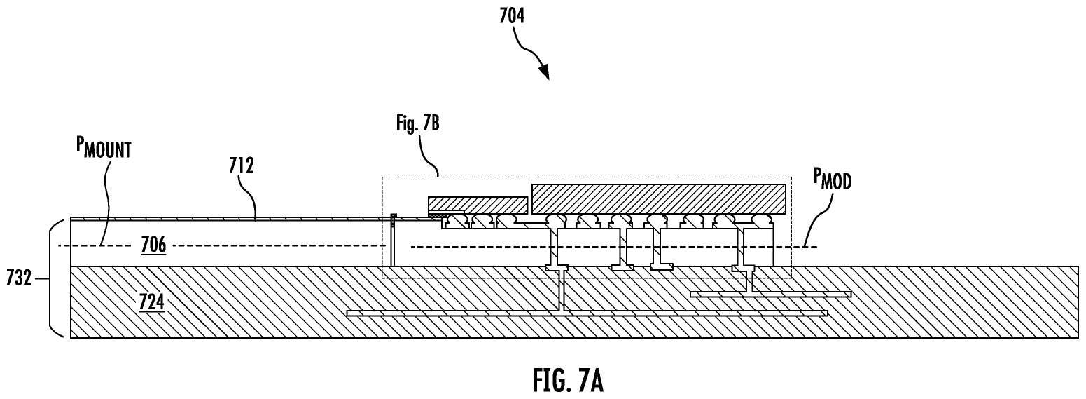

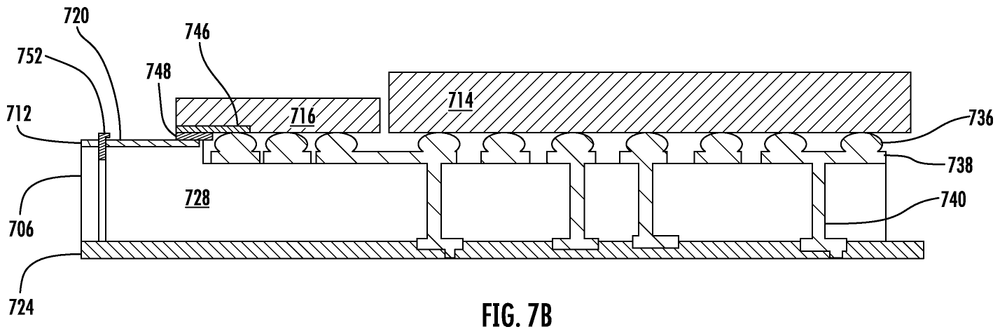

The embodiment of FIGS. 6A-6B illustrates an embodiment where an edge optical interface 652 is provided between a circuit board substrate and a module substrate that are provided in different planes. However, other embodiments may be provided where edge optical interfaces are used between a circuit board substrate and a module substrate that are provided in the same plane. This is illustrated in FIGS. 7A-7B. FIG. 7A illustrates a schematic view of an example module secured to an example circuit board, with an optical interface between the two. FIG. 7B illustrates an enhanced view of the module, circuit board, and optical interface illustrated in FIG. 7A.

Similar to the embodiments described above, the embodiment illustrated in FIGS. 7A and 7B includes a module 704 with a module substrate 728. The module substrate 728 may include one or more module waveguides 720. A circuit board 732 may also be provided with a circuit board substrate 706, and the circuit board substrate 706 may have one or more circuit board waveguides 712. In the illustrated embodiment, the circuit board substrate 706 and the module substrate 728 are provided in the same plane. Thus, the mounting plane (P_{MOUNT}) defined by the circuit board substrate 706 may be co-planar with the module plane (P_{MOD}) defined by the module substrate 728.

Similar to previous embodiments, the module 704 is provided with an ASIC 714 and a PIC 716 assembled on the module substrate 728. The ASIC 714 and the PIC 716 are provided on the same side of the module substrate 728 in the illustrated embodiment. The PIC 716 may include one or more PIC waveguide(s) 746, and a PIC optical interface 748 may be provided between the module waveguide(s) 720 and the PIC waveguide(s) 746.

The module 704 may also include electrical bumps 736, redistribution layers 738, and vias 740. The electrical bumps 736 are configured to contact the PIC 716 or the ASIC 714, and the redistribution layers 738 are configured to contact the electrical bumps 736. The electrical bumps 736, the redistribution layers 738, and the vias 740 may be configured to conduct electricity to or from at least two of the ASIC 714, the PIC 716, and the electrical layer 724 of the circuit board 732.

In the illustrated embodiment, an edge optical interface 752 is utilized. The edge optical interface 752 may contact an end face of a circuit board waveguide of the circuit board waveguide(s) 712. The edge optical interface 752 may also contact an end face of a module waveguide of the module waveguide(s) 720.

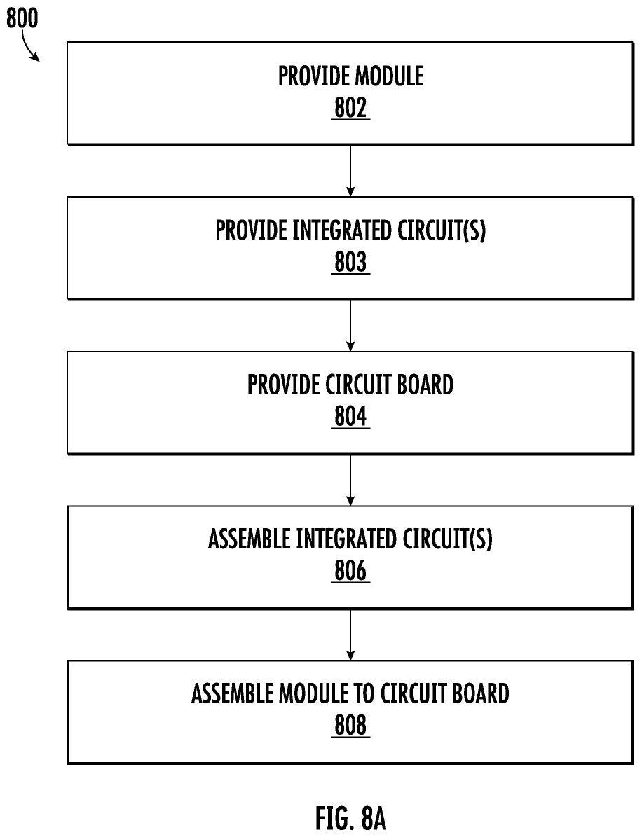

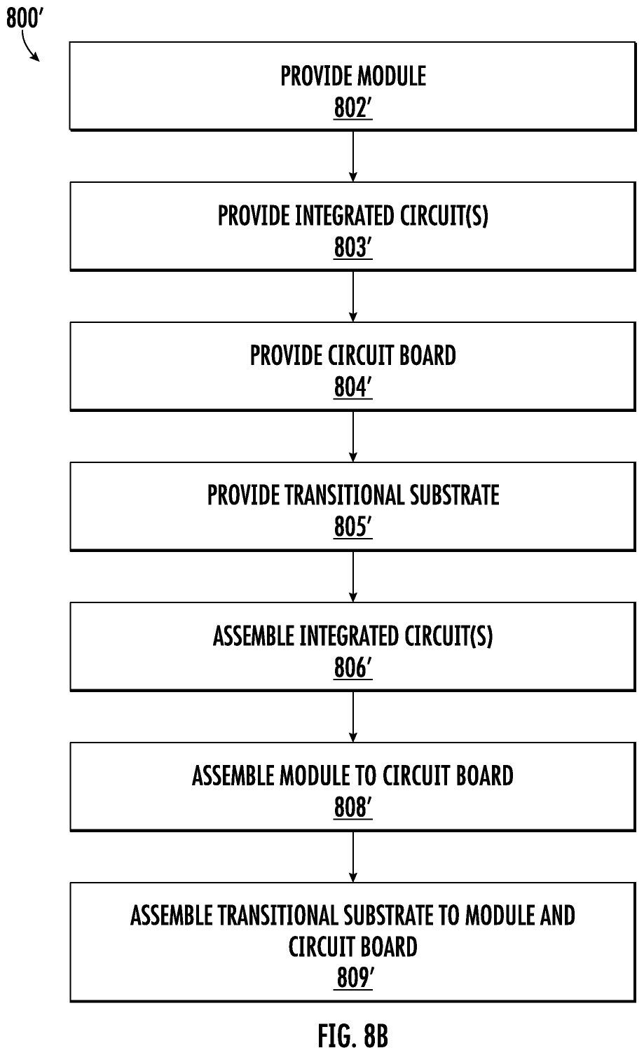

The electro-optical assemblies described herein may be formed using various manufacturing methods. The electro-optical assembly design may reduce the costs and complexity of manufacturing as compared to other similar assemblies. FIG. 8A is a flow chart illustrating a method 800 for forming an electro-optical assembly. Various components may be provided. At operation 802, a module is provided. This module may include a module substrate, and the module substrate may have one or more module waveguides. At operation 803, one or more integrated circuits are provided. The one or more integrated circuits may include one or more PICs, ASICs, and/or other integrated circuits. In some embodiments, the one or more integrated circuits may be provided alongside the module and operations 802 and 803 may be performed simultaneously. At operation 804, a circuit board is provided. The circuit board may include a circuit board substrate, and the circuit board substrate may have one or more circuit board waveguides.

The components may also be assembled together. At operation 806, one or more integrated circuit(s) are assembled. The integrated circuit(s) may be assembled on the module without the need to assemble any integrated circuit(s) directly to the circuit board. This may reduce manufacturing costs and increase the ease of assembly for users. At operation 808, the module may be assembled to the circuit board. This may be done in a manner that may properly align the module and the circuit board so that waveguides in the module align with waveguides in the circuit board for optical coupling. One or more fiducials or passive alignment features may be utilized to accurately position the substrates for low loss coupling. Assembly may also include the application of an optical interface between the waveguides of the module and the circuit board to enhance optical coupling.

FIG. 8B is a flow chart illustrating an alternative method 800′ where a transitional substrate is used. Various components may be provided. At operation 802′, a module is provided. This module may include a module substrate, and the module substrate may have one or more module waveguides. At operation 803′, one or more integrated circuits are provided. The one or more integrated circuits may include one or more PICs, ASICs, and/or other integrated circuits. In some embodiments, the one or more integrated circuits may be provided alongside the module and operations 802′ and 803′ may be performed simultaneously. At operation 804′, a circuit board is provided. The circuit board may include a circuit board substrate, and the circuit board substrate may have one or more circuit board waveguides. At operation 805′, a transitional substrate is provided, and this transitional substrate may include one or more transitional waveguides.

The components may also be assembled together. At operation 806′, one or more integrated circuit(s) are assembled. The integrated circuit(s) may be assembled on the module without the need to assemble any integrated circuit(s) directly to the circuit board. This may reduce manufacturing costs and increase the ease of assembly for users. At operation 808′, the module may be assembled to the circuit board. This may be done in a manner that may properly align the module and the circuit board so that waveguides in the module align with waveguides in the circuit board for optical coupling. One or more fiducials or passive alignment features may be utilized to accurately position the substrates for low loss coupling. At operation 809′, the transitional substrate may be assembled to the module and the circuit board. This may be done in a manner that may properly align the transitional substrate with the module substrate and the circuit board substrate so that transitional waveguides align with circuit board waveguides and module waveguides.

While various operations are illustrated in FIGS. 8A-8B and described above, the operations may be performed in any order unless stated otherwise. Certain operations may also be performed simultaneously. For example, all of the components may be provided at the same time so that operations 802, 803, and 804 are performed simultaneously. Additionally, certain operations may be omitted or additional operations may be performed.

It will therefore be readily understood by those persons skilled in the art that the present invention is susceptible of broad utility and application. Many embodiments and adaptations of the present invention other than those herein described, as well as many variations, modifications and equivalent arrangements, will be apparent from or reasonably suggested by the present invention and the foregoing description thereof, without departing from the substance or scope of the present invention. Accordingly, while the present invention has been described herein in detail in relation to its preferred embodiment, it is to be understood that this disclosure is only illustrative and exemplary of the present invention and is made merely for purposes of providing a full and enabling disclosure of the invention. The foregoing disclosure is not intended to be construed to limit the present invention or otherwise to exclude any such other embodiments, adaptations, variations, modifications and equivalent arrangements.

What is claimed is:

1. A method for forming an electro-optical assembly, comprising:
providing a module having a module substrate, the module substrate having a module waveguide;
providing a circuit board having a circuit board substrate, the circuit board substrate having a circuit board waveguide;
assembling at least one integrated circuit on the module; and
assembling the module to the circuit board so that the module waveguide is aligned with the circuit board waveguide for optical coupling.

2. The method of claim 1, wherein the at least one integrated circuit includes at least one photonic integrated circuit and an application specific integrated circuit.

3. The method of claim 2, wherein the at least one photonic integrated circuit is provided on a first side of the module substrate and the application specific integrated circuit is provided on a second side of the module substrate, wherein the module substrate includes a via that extends through the module substrate, wherein the via is configured to conduct electricity between at least two of the circuit board, the at least one photonic integrated circuit, and the application specific integrated circuit.

4. The method of claim 3, wherein the module further comprises electrical bumps, wherein the electrical bumps are configured to contact the at least one photonic integrated circuit or the application specific integrated circuit, wherein the electrical bumps are configured to conduct electricity between at least two of the circuit board, the at least one photonic integrated circuit, and the application specific integrated circuit.

5. The method of claim 3, wherein the at least one photonic integrated circuit includes two photonic integrated circuits.

6. The method of claim 2, wherein the at least one photonic integrated circuit is provided on a first side of the module substrate and the application specific integrated circuit is also provided on the first side of the module substrate, wherein the module further comprises electrical bumps and a redistribution layer, wherein the electrical bumps are configured to contact the at least one photonic integrated circuit or the application specific integrated circuit, wherein the redistribution layer is configured to contact the electrical bumps, wherein the redistribution layer and the electrical bumps are configured to conduct electricity to or from at least two of the circuit board, the at least one photonic integrated circuit, and the application specific integrated circuit.

7. The method of claim 2, wherein the circuit board substrate defines a mounting plane, wherein the module is assembled to the circuit board so that the module substrate is provided at a different plane than the mounting plane.

8. The method of claim 7, wherein the circuit board substrate and the module substrate form a recess, wherein the recess is formed in the mounting plane, wherein the at least one photonic integrated circuit is provided in the recess.

9. The method of claim 1, wherein assembling the module to the circuit board includes edge coupling the module substrate to the circuit board substrate.

10. The method of claim 9, wherein the edge coupling results in an edge optical interface contacting an end face of the circuit board waveguide and an end face of the module waveguide.

11. The method of claim 1, wherein the at least one integrated circuit includes a photonic integrated circuit waveguide, wherein assembling at least one integrated circuit on the module results in the module waveguide being aligned with the photonic integrated circuit waveguide.

12. The method of claim 1, wherein the circuit board is separated into an electrical layer and an optical layer, wherein a gap is provided between the electrical layer and the optical layer, and wherein assembling the module to the circuit board results in the module being placed in the gap.

13. The method of claim 1, further comprising providing a transitional substrate having a transitional waveguide.

14. The method of claim 13, further comprising assembling the transitional substrate to the module and the circuit board, wherein the circuit board substrate defines a mounting plane, wherein the module substrate is provided in the mounting plane, wherein the transitional substrate is not provided in the mounting plane, wherein the transitional waveguide is aligned with both the module waveguide and the circuit board waveguide.

15. The method of claim 1, wherein the module waveguide is a glass waveguide, a polymer waveguide, or a silicon nitrate waveguide, and wherein the circuit board waveguide is a glass waveguide, a polymer waveguide, or a silicon nitrate waveguide.

16. The method of claim 1, wherein the module substrate is a glass substrate, and wherein the circuit board substrate is a glass substrate.

17. An electro-optical assembly, comprising:
a module having a module substrate, the module substrate having a module waveguide;
a circuit board having a circuit board substrate, the circuit board substrate having a circuit board waveguide; and
at least one integrated circuit proximate to the module,
wherein the module is assembled to the circuit board so that the circuit board waveguide is aligned with the module waveguide for optical coupling.

18. The electro-optical assembly of claim 17, wherein the at least one integrated circuit includes at least one photonic integrated circuit and an application specific integrated circuit.

19. The electro-optical assembly of claim 18, wherein the at least one photonic integrated circuit is provided on a first side of the module substrate and the application specific integrated circuit is provided on a second side of the module substrate, wherein the module substrate includes a via that extends through the module substrate, wherein the via is configured to conduct electricity to or from at least two of the circuit board, the at least one photonic integrated circuit, and the application specific integrated circuit.

20. The electro-optical assembly of claim 18, wherein the at least one photonic integrated circuit is provided on a first side of the module substrate and the application specific integrated circuit is also provided on the first side of the module substrate, wherein the module further comprises electrical bumps and a redistribution layer, wherein the electrical bumps are configured to contact the at least one photonic integrated circuit or the application specific integrated circuit, wherein the redistribution layer is configured to contact the electrical bumps, wherein the redistribution layer and the electrical bumps are configured to conduct electricity to or from at least two of the circuit board, the at least one photonic integrated circuit and the application specific integrated circuit.
